(19) United States
(12) Patent Application Publication
(10) Pub. No.: US 2025/0164241 A1
(43) Pub. Date: May 22, 2025

(54) ERROR RESISTANT PHOTOMASK MEASUREMENT TECHNIQUES FOR DIFFERENT SUPPORT POSITIONS

(71) Applicant: CORNING INCORPORATED, CORNING, NY (US)

(72) Inventor: Thomas James Dunn, Penfield, NY (US)

(21) Appl. No.: 18/920,398

(22) Filed: Oct. 18, 2024

Related U.S. Application Data
(60) Provisional application No. 63/600,084, filed on Nov. 17, 2023.

(51) Int. Cl. G01B 11/30; G03F 1/60

(52) U.S. Cl. CPC G01B 11/306; G03F 1/60

(57) ABSTRACT

A method of determining a flatness of a substrate, the method including measuring a first flatness measurement of the substrate at a first orientation and a first tilt angle, measuring a second flatness measurement of the substrate at the first orientation and a second tilt angle different from the first tilt angle, generating a difference measurement between the first flatness measurement and the second flatness measurement, fitting the difference measurement to an orthogonal polynomial, generating an estimation of error based at least in part on using a scale factor and the difference measurement, the scale factor based on extracting orthogonal factors associated with the orthogonal polynomial, and generating a true flatness of the substrate by removing the estimation of error from the first flatness measurement.

This application claims the benefit of priority under 35 U.S.C § 120 of U.S. Provisional Application Ser. No. 63/600,084 filed on Nov. 17, 2023, the content of which is relied upon and incorporated herein by reference in its entirety.

### FIELD OF TECHNOLOGY

The present disclosure relates generally to photomask measurement and manufacturing, and more specifically to techniques for measuring the flatness of the photomask.

### BACKGROUND

Optical lithography is a key process used in the fabrication of various electronics, such as microelectronics and integrated circuits, among other examples, and such electronics may have a wide range of industrial, academic, and commercial applications (e.g., computers, vehicles, wearable devices such as smart watches, mobile electronic devices such as smartphones and tablets, and the like). Optical lithography (e.g., extreme ultraviolet (EUV) lithography) may be used to transfer images from a pattern (e.g., a master pattern) on a photomask (e.g., a photolithography mask, a photolithography reticle) to a semiconductor material (e.g., a crystalline silicon material). In some cases, the semiconductor material may include a photo-sensitive coating, such that exposing the photo-sensitive coating may enable one or more processes to be conducted on the semiconductor material. For example, after exposing the photo-sensitive coating, the semiconductor material may be processed to etch the pattern from the photomask into the semiconductor material or to replace the exposed pattern with a new material, among other processes. In some examples, this process may be repeated a quantity of times to create the semiconductor material and ultimately the electronic device (e.g., a final product).

In some cases, a flatness of the photomask may affect an accuracy of the pattern transferred to the semiconductor material. For example, if a flatness of the patterned surface of the photomask deviates from a desired flatness (e.g., a true flatness, an ideal plane), errors may be introduced during the physical patterning of the semiconductor material, such that the semiconductor material may not be patterned according to a desired imaging. In some such cases, the flatness of the photomask may be measured to ensure the flatness satisfies a desired flatness or to ensure the flatness is identified and accounted for when patterning the semiconductor material, so that errors in the flatness do not result in errors of the patterned semiconductor material.

### SUMMARY

The embodiments of the present disclosure relate to improved methods, systems, devices, and apparatuses for error resistant photomask measurement techniques for different support positions. Generally, the described techniques are directed to measuring a photomask at various orientations (e.g., rotated along an axis normal to a surface of the photomask) and tilt angles (e.g., relative to a vertical direction) and performing calculations to determine a flatness (e.g., a true flatness) of the photomask. For example, a flatness of the photomask may be measured by one or more interferometers at one or more orientations and one or more tilt angles, and a controller may use the measurements to determine a measurement of the flatness of the photomask, for example, a gravitationally error resistant measurement of the flatness of the photomask. In some such examples, the gravitationally error resistant measurement of the flatness of the photomask may be associated with a flatness of the photomask separate from (e.g., independent from) gravity acting on the photomask. The gravitationally error resistant measurement of the flatness of the photomask may be used for accurately patterning a substrate such that the flatness of the photomask is accounted for, and errors are not induced (e.g., during patterning) on the substrate as a result of deviations in the flatness of the photomask.

A first aspect of a method of determining a flatness of a substrate, the method comprising measuring a first flatness measurement of the substrate at a first orientation and a first tilt angle, measuring a second flatness measurement of the substrate at the first orientation and a second tilt angle different from the first tilt angle, generating a difference measurement between the first flatness measurement and the second flatness measurement, fitting the difference measurement to an orthogonal polynomial generating an estimation of error based at least in part on using a scale factor and the difference measurement, the scale factor based on extracting orthogonal factors associated with the orthogonal polynomial, and generating a true flatness of the substrate by removing the estimation of error from the first flatness measurement.

A second aspect of a method according to the first aspect, wherein the orthogonal polynomial is a Zernike polynomial.

A third aspect of a method according to the first or second aspect, wherein the second orientation is rotated 90 degrees from the first orientation.

A fourth aspect of a method according to the first through third aspects, wherein the substrate is a photomask.

A fifth aspect of a method according to the first through fourth aspects, further comprising measuring a third flatness measurement of the substrate at a second orientation different from the first orientation and the first tilt angle, rotating the third flatness measurement to match an orientation of the first flatness measurement to generate a modified third flatness measurement, and, subtracting the modified third flatness measurement from the first flatness measurement to generate an orientation factor.

A sixth aspect of a method according to the first through fifth aspects, further comprising dividing an orientation factor by a tilt factor to provide a scale factor and multiplying the first difference measurement by the scale factor to provide the estimation of error.

A seventh aspect of a method according to the sixth aspect, further comprising subtracting the estimation of error from the first flatness measurement to provide the true flatness of the substrate.

An eighth aspect of a method according to the sixth or seventh aspect, wherein the estimation of error is a deviation in flatness of the substrate caused from a gravitational force.

A ninth aspect of a method according to the sixth through eighth aspects, further comprising measuring a third flatness measurement of the substrate at a second orientation different from the first orientation and the first tilt angle, rotating the third flatness measurement to match an orientation of the first flatness measurement to generate a modified third flatness measurement, subtracting the modified third flatness measurement from the first flatness measurement to generate the orientation factor, and fitting the difference measurement to an orthogonal polynomial to generate the tilt factor.

A tenth aspect of a method according to the ninth aspect, wherein the orthogonal polynomial is a Zernike polynomial.

An eleventh aspect of a method according to the first through tenth aspects, further comprising patterning a semiconductor material based at least in part on modifying a positioning of patterned data on the substrate based at least in part on the true flatness of the substrate.

A twelfth aspect of a method according to the first through eleventh aspects, further comprising measuring a third flatness measurement of the substrate at a second orientation different from the first orientation and the first tilt angle, measuring a fourth flatness measurement of the substrate at the second orientation and the second tilt angle, generating a second difference measurement between the third flatness measurement and the fourth flatness measurement, and fitting the second difference measurement to an orthogonal polynomial.

A thirteenth aspect of a method according to the twelfth aspects, wherein the orthogonal polynomial is a Zernike polynomial.

A fourteenth aspect of a method according to the twelfth or thirteenth aspects, further comprising generating a second estimation of error based at least in part on using a scale factor and the second difference measurement, the scale factor based on extracting orthogonal factors associated with the orthogonal polynomial, and generating the true flatness of the substrate by removing the second estimation of error from the third flatness measurement.

A fifteenth aspects of a method according to the fourteenth aspects, further comprising averaging the difference from removing the estimation of error from the first flatness measurement with the difference from removing the second estimation of error from the third flatness measurement to generate the true flatness of the substrate.

A sixteenth aspect of a method according to the first through fifteenth aspects, wherein the first flatness measurement and the second flatness measurement are each measured by directing light at the substrate and comparing the light with light directed at a reference surface.

A seventeenth aspect of a method according to the first through sixteenth aspects, wherein the first tilt angle and the second tilt angle are each less than about 5 degrees.

An eighteenth aspects of a method according to the first through seventeenth aspects, the first tilt angle is from about 1 degree to about 2 degrees and the second tilt angle is from about 3 degrees to about 4 degrees.

A nineteenth aspect of a method according to the first through eighteenth aspects, further comprising positioning the substrate in contact with one or more support members of an interferometer.

A twentieth aspect of method of determining a flatness of a substrate, the method comprising measuring a first flatness measurement of the substrate at a first orientation and a first tilt angle, measuring a second flatness measurement of the substrate at the first orientation and a second tilt angle different from the first tilt angle, fitting the first flatness measurement to a first orthogonal polynomial and the second flatness measurement to a second orthogonal polynomial, generating a difference measurement between the first orthogonal polynomial and the second orthogonal polynomial, generating an estimation of error based at least in part on using a scale factor and the difference measurement, and generating a true flatness of the substrate by removing the estimation of error from the first flatness measurement.

A twenty-first aspect of a method according to the twentieth aspect, wherein the first orthogonal polynomial is a Zernike polynomial, and the second orthogonal polynomial is a Zernike polynomial.

A twenty-second aspect of an apparatus comprising a support configured to maintain a substrate at one or more orientations and one or more tilt angles using one or more support members and an interferometer configured to measure a first flatness measurement of the substrate at a first orientation and a first tilt angle and measure a second flatness measurement of the substrate at the first orientation and a second tilt angle different from the first tilt angle. The apparatus also comprising a controller configured to generate a difference measurement between the first flatness measurement and the second flatness measurement, fit the difference measurement to an orthogonal polynomial, generate an estimation of an error based at least in part on using a scale factor and the difference measurement, the scale factor based on extracting orthogonal factors associated with the orthogonal polynomial, and generate a true flatness of the substrate based at least in part on removing the estimation of the error from the first flatness measurement.

A twenty-third aspect of an apparatus according to the twenty-second aspect, wherein the substrate is a photomask.

A twenty-fourth aspect of an apparatus according to the twenty-second or twenty-third aspects, wherein the one or more support members comprise a support member positioned along a top surface of the substrate and a support member positioned along a bottom surface of the substrate.

A twenty-fifth aspect of an apparatus according to the twenty-second through twenty-fourth aspects, wherein the one or more support members are each a cantilever member extending from a base.

A twenty-sixth aspect of an apparatus according to the twenty-second through twenty-fifth aspects, further comprising a reference surface and one or more optical elements.

A twenty-seventh aspect of an apparatus according to the twenty-sixth aspect, wherein the reference surface is a Fizeau surface.

A twenty-eighth aspect of an apparatus according to the twenty-second through twenty-seventh aspects, wherein the second orientation is rotated 90 degrees from the first orientation.

A twenty-ninth aspect of an apparatus according to the twenty-second through twenty-eighth aspects, wherein the first tilt angle and the second tilt angle are each less than about 5 degrees.

A thirtieth aspect of an apparatus according to the twenty-second through twenty-ninth aspects, wherein the first tilt angle is from about 1 degree to about 2 degrees and the second tilt angle is from about 3 degrees to about 4 degrees.

### BRIEF DESCRIPTION OF THE DRAWINGS

FIG. 1 shows an example of a system that supports error resistant substrate measurement techniques for different support positions in accordance with aspects of the present disclosure.

FIGS. 2A, 2B, 2C, and 2D show examples of substrate orientation diagrams that support error resistant substrate measurement techniques for different support positions in accordance with aspects of the present disclosure.

FIG. 3 shows an example of a process flow that supports error resistant substrate measurement techniques for different support positions in accordance with aspects of the present disclosure.

FIG. 4 shows a block diagram of an action response component that supports error resistant substrate measurement techniques for different support positions in accordance with aspects of the present disclosure.

FIGS. 5 and 6 show flowcharts illustrating methods that support error resistant substrate measurement techniques for different support positions in accordance with aspects of the present disclosure.

### DETAILED DESCRIPTION

A semiconductor material may be patterned through the use of optical lithography to facilitate the formation of various electronic devices. A substrate, such as a photomask (e.g., a photolithography mask, a reticle) is configured to transfer the pattern (e.g., pattern data, images) to the semiconductor material such that the semiconductor material is exposed (e.g., marked) by the pattern. After the semiconductor material is patterned via the photomask, one or more manufacturing operations (e.g., etching, depositing) may be performed in accordance with the pattern to process the semiconductor material and ultimately produce the electronic device. However, deviations in a flatness (e.g., planarity) of the photomask from an ideal plane or from a desired flatness may introduce related deviations (e.g., errors) in the patterning of the semiconductor material when transferring the pattern. Thus, it is desirable to measure the flatness of the photomask before patterning the semiconductor material, such that deviations in the flatness may be identified and accounted for (e.g., adjusted for) during the patterning of the semiconductor material.

In embodiments, the flatness of a photomask may be measured and determined with relatively reduced or no deviations in flatness (errors in the flatness measurement) due to gravitational force acting on the photomask. That is, the system disclosed herein may separate deviations in the flatness of the photomask induced by the gravitational force from an actual flatness of the photomask, wherein the actual flatness is the true flatness of the photomask. Therefore, in the embodiments disclosed herein, the gravitational component of the flatness measurement is removed from the flatness measurement to provide the true flatness of the photomask.

In embodiments, the flatness of a substrate may be measured at one or more orientations and may then fit the measurements to orthogonal polynomials such as Zernike polynomials to generate an estimation of error associated with the gravitational force. The system may remove the estimation of error from the flatness measurement to determine an error-resistant measurement of the flatness (the true flatness) of the substrate. As in known in the art, Zernike polynomials can be applied to describe mathematically 3-D wavefront deviations. Each Zernike polynomial describes a specific form of surface deviation such that combining two or more Zernike polynomials can describe more complex surface shapes. In principle, by including a sufficient number of Zernike polynomials (commonly referred to as “terms”), any wavefront deformation can be described to a desired degree of accuracy. Each Zernike term is referenced by a polynomial order (0, 1, 2, 3, 4, 5, 6, 7, etc.) and is grouped according to an angular frequency (θ) and a radial order. Furthermore, as is also known in the art, the Zernike polynomials may be referred to as “even” or “odd” such that the even Zernike polynomials correspond to polynomials with even angular frequencies (θ0, 2θ, 4θ, 6θ, etc.) and the odd Zernike polynomials correspond to polynomials with odd angular frequencies (1θ, 3θ, 5θ, 7θ, etc.).

Aspects of the disclosure are initially described in the context of a system implementing rotational error resistant photomask measurement techniques. Further aspects of the disclosure are described in the context of photomask orientation diagrams, and process flows for a system implementing rotational error resistant photomask measurement techniques. Aspects of the disclosure are further illustrated by and described with reference to a block diagrams and flowcharts that relate to rotational error resistant photomask measurement techniques.

This description provides examples, and is not intended to limit the scope, applicability or configuration of the principles described herein. Rather, the ensuing description will provide those skilled in the art with an enabling description for implementing various aspects of the principles described herein. As can be understood by one skilled in the art, various changes may be made in the function and arrangement of elements without departing from the application.

It should be appreciated by a person skilled in the art that one or more aspects of the disclosure may be implemented in a system to additionally or alternatively solve other problems than those described herein. Further, aspects of the disclosure may provide technical improvements to “conventional” systems or processes as described herein. However, the description and appended drawings only include example technical improvements resulting from implementing aspects of the disclosure, and accordingly do not represent all of the technical improvements provided within the scope of the claims and the disclosure.

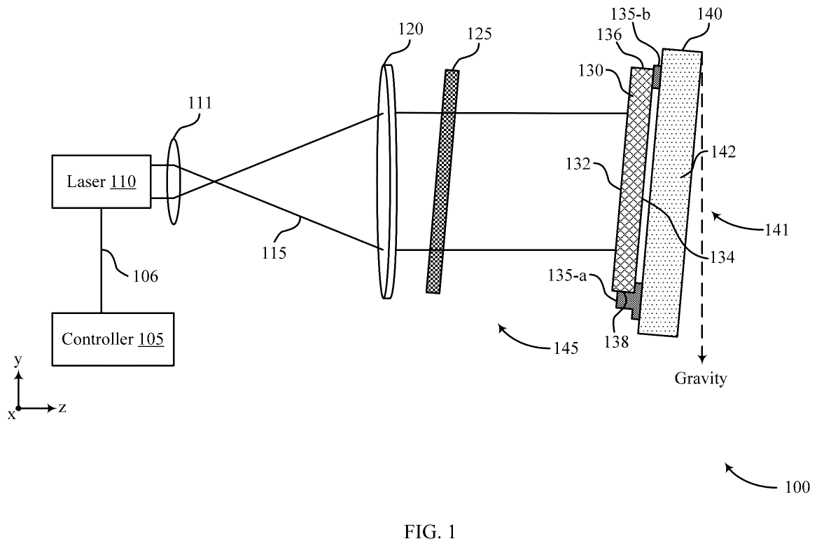

FIG. 1 shows an example of a system 100 that provides error resistant photomask measurements for different support positions of the photomask, in accordance with aspects of the present disclosure. In particular, the system 100 includes various measurement components operable to measure a flatness of a substrate 130. For illustrative purposes, aspects of the system 100 may be described with reference to an x-direction, a y-direction, and a z-direction of the illustrated coordinate system. For example, the system 100 may illustrate a side view of the system 100 in an yz-plane. In some examples, the y-direction may be illustrative of a direction opposite to gravitational force, and each of the measurement components may extend for some distance along the x-direction. Although the system 100 illustrates examples of relative sizes and quantities of various features, aspects of the system 100 may be implemented with other relative sizes or quantities of such features in accordance with examples as disclosed herein.

The substrate 130 may be a photomask or a blank, for example. The substrate 130 may be coated glass material or uncoated glass material. As shown in FIG. 1, substrate 130 comprises a first surface 132, a second surface 134, a top surface 136, and a bottom surface 138. System 100 may measure the flatness of the first surface 132 and/or the second surface 134.

The system 100 may include a controller 105 configured to facilitate operations of the system 100. The controller 105 may include one or more processors configured to perform operations in accordance with configurations, algorithms, or programs stored at the controller 105 or an external memory system. For example, the controller 105 may include a non-transitory computer readable medium configured to store instructions including code operable to cause the controller 105 to perform operations with the system 100. The controller 105 may be configured to communicate signaling with an interferometer 145 via, for example, one or more interfaces. For example, the controller 105 may communicate one or more commands to the interferometer 145 to measure the flatness of the substrate 130 (e.g., to collect measurement data associated with a shape of the substrate 130). Additionally, the controller 105 may receive measurements of the flatness of the substrate 130 from the interferometer 145. The interferometer 145 may be, for example, a Fizeau interferometer 145 configured to measure the flatness of the substrate 130 via a quantity of components. For example, the interferometer 145 may include components associated with producing and targeting light at the substrate 130 and components associated with comparing light from the substrate 130 to a reference surface 125 to determine deviations in the flatness of the substrate 130. It is also contemplated, in some embodiments, that system 100 comprises more than one interferometer 145.

The controller 105 may be configured to communicate with the interferometer 145 by signaling with a laser 110 (e.g., a laser light source, a laser diode) via an interface 106 (e.g., a bus) that couples the controller 105 with the laser 110. For example, the controller 105 may communicate one or more commands to the laser 110 (via the interface 106) to initialize performing one or more operations associated with measuring the flatness of the substrate 130. The laser 110 may be configured to output one or more laser beams 115 associated with measuring the flatness of the substrate 130. As shown in FIG. 1, the interferometer 145 may include a focusing element 111 configured to focus the one or more laser beams 115 at one or more optical elements 120. The one or more optical elements 120 of the interferometer may be configured to orient the one or more laser beams 115 at a reference surface 125 or at the first surface 132 of the substrate 130, or both. In some cases, the one or more optical elements 120 may be configured to direct, refract, and/or focus the one or more laser beams 115, such that the one or more laser beams 115 illuminate an entire surface (or a portion thereof) of the reference surface 125 and/or the first surface 132 of the substrate 130. For example, the laser 110 may output the laser beams 115, which may be focused by the focusing element 111, to direct the laser beams 115 at the optical element 120, which may project the laser beams 115 to the reference surface 125 and to the substrate 130.

The reference surface 125 is also known as a Fizeau surface and is a relatively large flat surface with a known flatness. As discussed further below, the reference surface 125 is used as a reference for comparison with substrate 130 in order to determine the flatness of substrate 130. The reference surface 125 may be comprised of fused silica, in some embodiments.

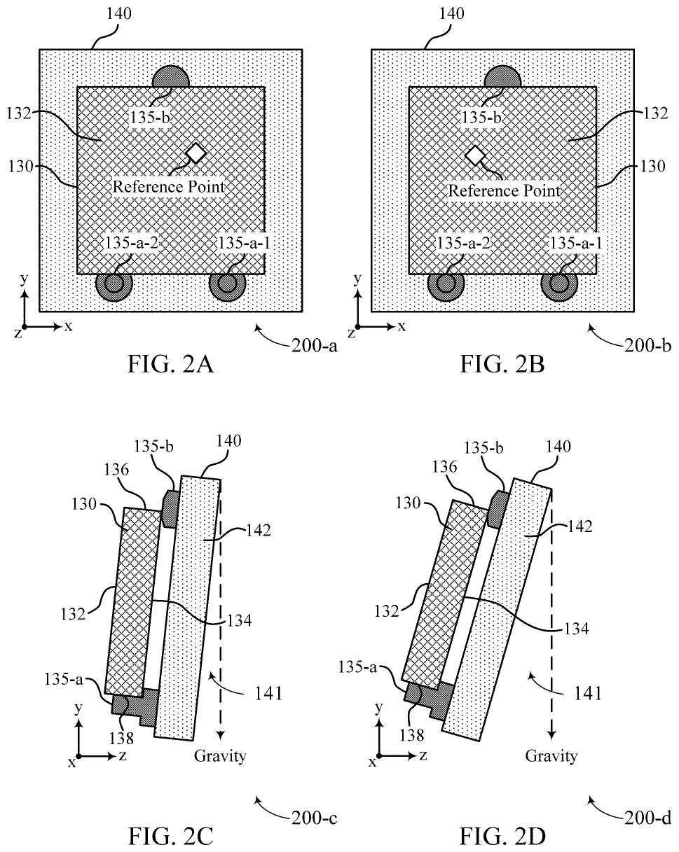

As also shown in FIG. 1, the interferometer 145 further comprises a support 140 to maintain the substrate 130 in a desired position at a desired orientation. The support 140 comprises at least two support members 135-a, 135-b. Support member 135-a may comprise two support members 135-a-1 and 135a-2 that are each positioned along a bottom surface of substrate 130 as shown in FIGS. 2A-2D. Furthermore, support member 135-b may be positioned along a top surface of substrate 130. However, it is also contemplated that the support members 135-a-1, 135-a-2, and 135-b may be positioned along different portions and/or surfaces of substrate 130 than specifically disclosed herein. As shown in FIG. 1, support members 135-a-1, 135-a-2, and 135-b are each a cantilever member extending from a base 142 of support 140. In the embodiments disclosed herein, the support members 135-a-1 and 135-a-2 only directly contact the bottom surface 138 and a chamfered edge at the bottom of the substrate 130. Furthermore, support member 135-b only directly contacts a chambered edge at the top of the substrate 130. Therefore, support members 135-a-1, 135-a-2, and 135-b do not directly contact either the first surface 132 or the second surface 134 of the substrate 130.

The support members 135-a and 135-b are configured to maintain the substrate 130 a distance from the base 142 of support 140. In some embodiments, the second surface 134 of the substrate 30 is maintained a distance from the base 142 of support 140 while being parallel to the base 142 of support 140.

The support 140 may be maintained at an angle 141 relative to the y-axis vertical direction. Therefore, base 142 may be maintained at the angle 141 relative to the y-axis vertical direction. Because support 140 is maintained at this angle, the substrate 130 is also maintained at the angle 141 relative to the y-axis vertical direction. In particular, angle 141 is defined herein as the angle between the second surface 134 of the substrate 130 and the y-axis vertical direction. Furthermore, angle 141 is also referred to herein as the “tilt angle” of the substrate 130. The value of angle 141 may be adjusted to change the magnitude of the gravitational force acting on the substrate 130, such that larger values of angle 141 correspond to the substrate 130 being slanted to a greater degree relative to the y-axis and that smaller values of angle 141 correspond to the substrate 130 being oriented more vertical along the y-axis.

When the substrate 130 is in a horizontal position, gravity acts on the substrate 130 in a direction orthogonal to surface 132 of the substrate 130. The magnitude of the gravitational force acting on the substrate 130 is relatively less when the substrate 130 is oriented more vertical (when the value of angle 141 is relatively smaller). Furthermore, the flatness measurement of the substrate 130 may be affected by the magnitude of the gravitational force acting on the substrate 130. Substate 130 is not a completely rigid component and, therefore, is susceptible to deflection when in a horizontal position due to the gravitational force. Stated another way, when the substrate 130 is in a horizontal position, the first surface 132 and the second surface 134 of the substrate 130 may slightly sag downward due to gravity. Although the deflection may be very small, such deflection may cause a traditional interferometer to inaccurately measure the flatness of the substrate. The traditional interferometer may inaccurately consider this deflection from gravity as part of the true flatness of the substrate. However, when the substrate 130 is oriented in a more vertical position (when the value of angle 141 is relatively smaller), it is less susceptible to the gravitational force and, therefore, does not have such sag (or has a reduced amount of sag). Because the magnitude of the gravitational force acting on the substrate 130 is less when the substrate is oriented more vertical, the substrate is also less prone to errors in flatness measurement caused from such gravitational forces.

Although a more vertical orientation of the substrate 130 is beneficial in that it provides more accurate flatness measurements, such must also be balanced with the stability of the substrate 130. The substrate 130 may be subject to relatively more vibrations and greater instability as the value of angle 141 is decreased, such that the substrate 130 is more prone to falling from the support 140. Thus, the value of angle 141 should be balanced to provide accurate measurements while preventing the substrate 130 from falling off the support 140. In embodiments, the value of angle 141 may be maintained between about 1 degree and about 5 degrees (to provide the desirable balance between stability and gravitational influence). The support members 135-a-1, 135-a-2, and 135-b, along with base 142, maintain the substrate 130 at the desired angle 141 between about 1 degree and about 5 degrees. It is noted that even at these ranges of the desired angle 141, the substrate 130 may still experience some deflection from gravity, even though small, for example, a deflection of about 20 nm to about 50 nm.

In embodiments, the interferometer 145 may include one or more light receptive components such that light reflected from the first surface 132 of the substrate 130 may be compared to light reflected from the reference surface 125 to determine differences in shape between the first surface 132 of the substrate 130 and the reference surface 125 (to ultimately measure the true flatness of the substrate 130). For example, the interferometer 145 may include a detector array, which may comprise one or more cameras configured to receive light directed from the first surface 132 of the substrate 130 or the reference surface 125, or both. In some such examples, the interferometer 145 may include one or more refractory lenses configured to direct light reflected from the first surface 132 of the substrate 130 or the reference surface 125, or both, to the detector array.

The controller 105 is configured to modify one or more parameters of the interferometer 145 to determine the shape and flatness of the first surface 132 of substrate 130. For example, the controller 105 may modify a brightness, wavelength, spatial coherence, or angle of illumination of the laser 110. Additionally or alternatively, the controller 105 may modify a number of measurement frames, a size of each measurement frame, or an integration time of the detector array. Additionally or alternatively, the controller 105 may control movements of the support 140 to modify the position or alignment of the support 140 (and, thus, also modify the position or alignment of the substrate 130). For example, the controller 105 may cause the support 140 to pivot to change the angle 141 of the substrate 130. In some embodiments, controller 105 may initiate other subsystems (such as a robot) to remove and reposition the substrate 130 in order to rotate the substrate 130 by, for example, 90 degree increments in its plane.

The flatness measurement of the first surface 132 of the substrate 130 comprises an assessment of the planarity of the first surface 132 and any deformation in such planarity from a completely flat, ideal plane. The substrate 130 itself comprises its true flatness, which is a measurement of the flatness of just the surface of the substrate 130. However, gravitational force acting on the substrate together with the support points 135-a and 135-b may cause deviations from the true flatness of the substrate. Such forces may cause the flatness measurement to be deviated from its true flatness. More specifically, the magnitude of the gravitational force acting on the substrate may cause the substrate to slightly sag, thus causing the flatness measurement to show a larger deviation from the ideal plane. Therefore, in such cases, the measured flatness of the substrate may be different than the true flatness of the substrate. As discussed further below, measurement errors in the interferometer itself may also cause deviations (errors) in the true flatness measurement of the substrate. It is important to accurately measure the flatness of the substrate in order to pattern a semiconductor material using the substrate, as discussed above. Thus, deviations in the flatness measurement (such as those caused by the gravitational force acting on the substrate or by measurement errors in the interferometer) may introduce unwanted deviations when patterning the semiconductor material.

In accordance with the embodiments disclosed herein, the system 100 is configured to determine the true flatness of the substrate 130 with relatively reduced or no deviations in flatness (errors in the flatness measurement) due to gravitational forces acting on the substrate 130 or from measurement errors from the interferometer. That is, the system 100 may separate deviations in the flatness of the substrate 130 induced by the gravitational forces from the true flatness of the substrate 130. Therefore, in the embodiments disclosed herein, the gravitational component and the interferometer measurement error component of the flatness measurement are removed from the flatness measurement to provide the true flatness of the substrate.

The interferometer 145 according to the embodiments disclosed herein, measures the flatness of the substrate 130 when the substrate is in non-horizontal positions in order to prevent (or reduce) any deflection of the substrate caused by gravitational forces. Furthermore, the interferometer 145 measures the flatness of the substrate 130 at one or more orientations of the substrate and at one or more angles 141, as discussed further below. After measuring the flatness of the substrate 130 at the one or more orientations and the one or more angles 141, the system 100 (e.g., the controller 105) extracts Zernike factors from the measurements and uses the Zernike factors to generate an estimation of error associated with the gravitational force. The system may remove the estimation of error from the flatness measurement to determine an error-resistant measurement of the flatness (the true flatness) of the substrate 130. Thus, the system 100 may provide a more accurate measurement of the true flatness of the substrate 130 as compared to traditional interferometers, which can then be used to modify a positioning of patterned data on the substrate 130 such that that the patterned data may be more accurately transferred to a semiconductor material during patterning. Additionally, the system 100 may be configured to account for rotationally symmetric errors in the flatness measurement of the substrate 130, which may have been otherwise unaccounted for with traditional interferometers.

FIGS. 1A-2D show examples of orientation diagrams 200-a, 200-b, 200-c, and 200-d in accordance with embodiments of the present disclosure. The orientation diagrams may implement or be implemented by aspects of system 100, as described with reference to FIG. 1. The orientation diagrams depict various orientations and angles for measuring a flatness of the substrate 130. For illustrative purposes, aspects of the orientation diagrams may be described with reference to an x-direction, a y-direction, and a z-direction of the illustrated coordinate system. For example, the orientation diagrams 200-a and 200-b may illustrate a front view of the substrate 130 in an xy-plane that shows the first surface 132 of the substrate 130, whereas the orientation diagram 200-c and 200-d may illustrate a sideview of the substrate 130 in a yz-plane. In some examples, the y-direction may be illustrative of a direction opposite to the gravitational forces, and each of the components may extend for some distance along the x-direction or the z-direction, respectively. Although the orientation diagrams illustrate examples of relative sizes and quantities of various features, aspects of the orientation diagrams may be implemented with other relative sizes or quantities of such features in accordance with examples as disclosed herein.

The flatness of the surface of the substrate 130 may be measured at one or more orientations and one or more tilt angles. Each of the different orientations of the substrate 130 may be separated by a respective degree angle, such as by a 90 degree angle, such that each orientation may represent a 90 degree incremental rotation along an axis (e.g., an axis in the z-direction) normal to a surface of the substrate 130. In other embodiments, the respective degree angle of the different orientations is, for example, 45 degrees, 180 degrees, 270 degrees. However, other angles than those specifically disclosed herein may be used. A robotic mechanism (not shown) may detach the substrate 130 from support 140 to rotate the substrate to a different orientation and then reposition the substrate 130 on the support 140. As shown in FIG. 2A, the substrate 130 is in a first orientation. In this example, the robotic mechanism then picks up the substrate 130 and removes the substrate 130 from the support 140. The robotic mechanism then rotates the substrate 130 90 degrees in a counterclockwise direction and repositions the substrate 130 on the support 140, as shown in FIG. 2B. Therefore, FIG. 2B shows the substrate 130 in a second orientation after it has been rotated. For illustrative purposes, a reference point is shown in FIGS. 2A and 2B to depict the rotation of the substrate 130. The interferometer 145 measures the flatness of the substrate 130 at each orientation of the substrate, as also discussed further below. In some embodiments, the interferometer 145 measures the substrate 130 at two different orientations.

Furthermore, the flatness of the substrate 130 is measured at different tilt angles of the substrate, such that each tilt angle comprises a different value of angle 141. More specifically, the substrate 130 may be moved to a first tilt angle such that the substrate 130 is at a first angle 141 with respect to the vertical y-axis. Then, support 140 may move the substrate 130 to a second angle 141 with respect to the vertical y-axis such that the substrate 130 is at a second tilt angle. FIG. 2C shows the substrate 130 at the first tilt angle and FIG. 2D shows the substrate 130 at the second tilt angle. In some embodiments, the first tilt angle is smaller than the second tilt angle. For example, the first tilt angle may be from about 1 degree to about 2 degrees and the second tilt angle may be from about 3 degrees to about 4 degrees. The interferometer 145 measures the flatness of the substrate 130 at each tilt angle of the substrate, as also discussed further below. In some embodiments, the interferometer 145 measures of the flatness of the substrate 130 at two different tilt angles.

The flatness of the substrate 130 may be measured, via the interferometer 145, at combinations of the different orientations and tilt angles to generate respective flatness measurements of the substrate 130. For example, the flatness of the substrate 130 may be measured at the first orientation and the first tilt angle to generate a first flatness measurement of the substrate 130. Further, the flatness of the substrate 130 may be measured at the first orientation and the second tilt angle to generate a second flatness measurement of the substrate 130. Similarly, the flatness of the substrate 130 may be measured at the second orientation and the first tilt angle to generate a third flatness measurement of the substrate 130. And, in some embodiments, the flatness of the substrate 130 may be measured at the second orientation and the second tilt angle to generate a fourth flatness measurement of the substrate 130. The controller 105 may use one or more of the first flatness measurement, the second flatness measurement, the third flatness measurement, and/or the fourth flatness measurement to generate the true flatness of the substrate 130 in which deviations in the flatness of the substrate 130 induced by the gravitational force are removed.

Each of the first, second, third and fourth flatness measurements may include deviations (errors), which are removed when calculating the final, true flatness of the substrate 130. For example, the substrate 130 will experience gravitational force when mounted on support 140 (even though the substrate is not in a horizontal position, it may still experience some minor deflection (sag) from gravity). The gravitational force causes deviations in each of the first, second, third, and fourth flatness measurements. Furthermore, the interferometer 145 may have internal inaccuracies (even if minor) that may contribute to the measured flatness of the substrate. As an example, wavefront errors in the interferometer 145 may contribute to the measured flatness. In the embodiments disclosed herein, the deviations and inaccuracies in the first, second, third, and fourth flatness measurements are determined and removed in order to provide the true flatness of the substrate 130.

In equation (1) below, M represents the true flatness of the substrate 130 (at each of the first, second, third, and fourth flatness measurements) without any influence from gravitational force or any other wavefront errors, G represents deviation in the true flatness caused from the gravitational force, and W represents deviation in the true flatness caused from the interferometer 145 (such as wavefront errors from the interferometer). The sum of M, G, and W is the measured flatness F (at each of the first, second, third, and fourth flatness measurements). In embodiments, F is the flatness measured by the interferometer 145. As discussed further below, in embodiments of the present disclosure, the deviations in the true flatness caused from the gravitational force (G) is determined and removed from the measured flatness (F) to determine the true flatness (M) of the substrate.

$$F = M + G + W \qquad ( 1 )$$

It is noted that, in embodiments, the deviation errors caused from the interferometer (W) may be removed during a calibration process of the interferometer 145, so the value of W may be relatively small (e.g., about 3 nm or less).

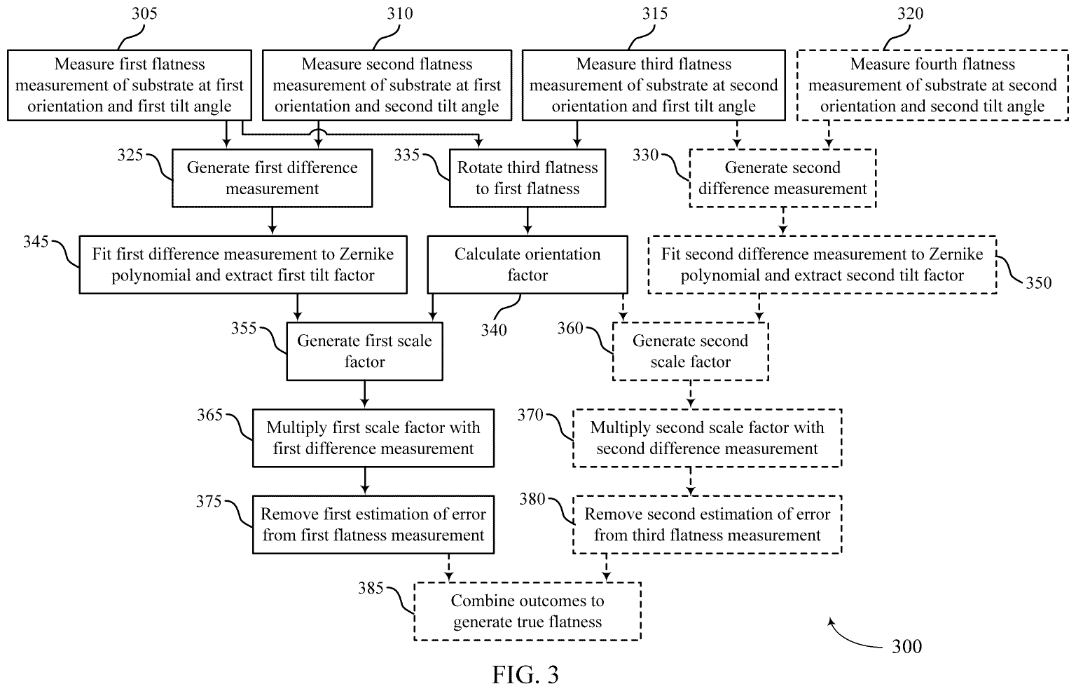

FIG. 3 shows an example of a process 300 for measuring the true flatness (M) of the substrate 130, in accordance with embodiments of the present disclosure. The process 300 may illustrate aspects of measuring the true flatness of the substrate 130, as described with reference to FIGS. 1-2D. In the following description, the steps of process 300 may be performed in different orders or at different times. For example, some of the steps and techniques described herein may be reordered, arranged, or otherwise rearranged to produce similar results, and the examples provided herein should not be considered limiting to the scope of the disclosure or the claims. For instance, and as described below, one or more aspects of the present disclosure may be performed via a different ordering or combination of steps than those described herein.

At steps 305, 310, 315, and 320 of process 300, the interferometer 145 measures the flatness of the substrate 130 at different orientations and tilt angles as described with reference to the orientation diagrams 200-a, 200-b, 200-c, and 200-d. The flatness of the substrate 130 at each of these steps may be measured as described herein with reference to FIG. 1, such that the system 100 may perform the measurements. For example, the interferometer 145 may measure and compare light detected from one or more laser beams 115 illuminating surfaces of a reference surface 125 and a surface of the substrate 130.

In particular, at step 305, the flatness of the substrate 130 is measured at a first orientation and a first tilt angle to provide the first flatness measurement. At step 310, the flatness of the substrate 130 is measured at the first orientation and a second tilt angle to provide the second flatness measurement. At step 315, the flatness of the substrate 130 is measured at the second orientation and the first tilt angle to provide the third flatness measurement. And, at step 320, the flatness of the substate 130 is measured at the second orientation and the second tilt angle to provide the fourth flatness measurement. In embodiments, the substrate 130 is rotated 90 degrees from the first orientation to the second (so that the second orientation is 90 degrees from the first orientation). Furthermore, in embodiments, the first tilt angle is in the range from about 1 degree to about 2 degrees, and the second tilt angle is in the range from about 3 degrees to about 4 degrees. As discussed above, a robotic arm, for example, may move the substrate 130 between the first and second orientations, and support 140 may move the substrate 140 between the different tilt angles.

It is noted that the first, second, third, and fourth flatness measurements each correspond to the F term in equation (1) above. In embodiments disclosed herein, using process 300, the G and W terms are determined and removed from the F term to determine the true flatness (the M term) of the substrate. In order to determine the G term, the different flatness measurement maps generated herein at the different orientations and tilt angles are compared to determine the effect of gravity on the substrate.

It is also noted that, in embodiments, process 300 may not comprise each of steps 305 through 320. In embodiments, process 300 may comprise only one or more of steps 305, 310, 315, and 320. For example, process 300 may only comprise step 305 or only steps 305 and 310.

At step 325 of process 300, the controller 105 may generate a first difference measurement, which is a difference between the first flatness measurement and the second flatness measurement. With reference to equation (1) above, each of the first flatness measurement and the second flatness measurement is a sum of the M, G, and W terms. More specifically, equation (2) below shows the first flatness measurement F₁ is the sum of the flatness of the substrate 130 at the first orientation and the first tilt angle (M₀), deviations in the flatness caused from the gravitational force (G₁), and deviations in the flatness caused from the interferometer 145 measurement errors (W). Furthermore, equation (3) below shows the second flatness measurement F₂ is the sum of the flatness of the substrate 130 at the first orientation and the second tilt angle (M₀), deviations in the flatness caused from the gravitational force (G₂), and deviations in the flatness caused from the interferometer 145 measurement errors (W). It is noted that both the first and second flatness measurements in equations (2) and (3) comprise the same M₀ term, which represents the substrate at the first orientation. Furthermore, the gravitational force on the substrate 130 may be different when the substrate is at the first tilt angle for the first flatness measurement compared to when the substrate is at the second tilt angle for the second flatness measurement. Therefore, the gravitational force is shown as G₁ and G₂ in equations (2) and (3), respectively, to show this difference.

$${F}_{1} = {M}_{0} + {G}_{1} + W \qquad ( 2 )$$

$${F}_{2} = {M}_{0} + {G}_{2} + W \qquad ( 3 )$$

When subtracting the second flatness measurement F₂ from the first flatness measurement F₁ in step 325, the following calculation results:

$${F}_{1} - {F}_{2} = ( {M}_{0} + {G}_{1} + W ) - ( {M}_{0} + {G}_{2} + W ) = {G}_{1} - {G}_{2} \qquad ( 4 )$$

Because the first flatness measurement F₁ and the second flatness measurement F₂ both comprise the same M₀ and W terms, these terms cancel out. It is noted that both the first and second flatness measurements have the same M₀ term because the substrate 130 is at the same orientation for each of the first and second flatness measurements. The difference G₁-G₂ in calculation (4) above is the first difference measurement.

Similarly, at step 330 of process 300, the controller 105 may generate a second difference measurement, which is a difference between the third flatness measurement and the fourth flatness measurement. With reference to equation (1) above, each of the third flatness measurement and the fourth flatness measurement is a sum of the M, G, and W terms. More specifically, equation (5) below shows the third flatness measurement F₃ is the sum of the flatness of the substrate 130 at the second orientation and the first tilt angle (M₉₀), deviations in the flatness caused from the gravitational force (G₃), and deviations in the flatness caused from the interferometer 145 measurement errors (W). Furthermore, equation (6) below shows the fourth flatness measurement F₄ is the sum of the flatness of the substrate 130 at the second orientation and the second tilt angle (M₉₀), deviations in the flatness caused from the gravitational force (G₄), and deviations in the flatness caused from the interferometer 145 measurement errors (W).

In equations (2) and (3) above, M₀ refer to the flatness at the 0 degree orientation, while in equations (5) and (6), M₉₀ refers to the flatness after the substrate has been rotated 90 degrees to the second orientation. Furthermore, the gravitational force on the substrate 130 may be different when the substrate is at the first tilt angle for the third flatness measurement compared to when the substrate is at the second tilt angle for the fourth flatness measurement. Therefore, the gravitational force is shown as G₃ and G₄ in equations (5) and (6), respectively, to show this difference.

$${F}_{3} = {M}_{90} + {G}_{3} + W \qquad ( 5 )$$

$${F}_{4} = {M}_{90} + {G}_{4} + W \qquad ( 6 )$$

When subtracting the fourth flatness measurement F₄ from the third flatness measurement F₃ in step 330, the following calculation results:

$${F}_{3} - {F}_{4} = ( {M}_{90} + {G}_{3} + W ) - ( {M}_{90} + {G}_{4} + W ) = {G}_{3} - {G}_{4} \qquad ( 7 )$$

Because the third flatness measurement F₃ and the fourth flatness measurement F₄ both comprise the same M₉₀ and W terms, these terms cancel out. It is noted that both the third and fourth flatness measurements have the same M₉₀ term because the substrate 130 is at the same orientation for each of the third and fourth flatness measurements. The difference G₃-G₄ in calculation (B) above is the second difference measurement.

At step 335, controller 105 rotates the data set of the third flatness measurement so that the orientation is changed from the second orientation to the first orientation. This new data set (the “modified third flatness measurement”) is similar to the data set of the first flatness measurement because both flatness measurements are now comprised of the same M₀ term. However, the G term is different between the modified third flatness measurement and the first flatness measurement because the data set has been rotated. The G_{3′} term of the modified third flatness measurement can then be used to calculate an orientation factor.

At step 340, the orientation factor is calculated by subtracting the modified third flatness measurement F₃, from the first flatness measurement F₁, which provides the following calculation:

$${F}_{1} - {F}_{{3}^{′}} = ( {M}_{0} + {G}_{1} + W ) - ( {M}_{0} + {G}_{{3}^{′}} + W ) = {G}_{1} - {G}_{{3}^{′}} \qquad ( 8 )$$

The G₁-G_{3′} map is then fit to a Zernike polynomial to derive the z5 astigmatism Zernike factor, which is referred to herein as: z5(G₁-G_{3′}). The z5 astigmatism factor is associated with a fifth order Zernike polynomial (20). The z5 astigmatism Zernike factor is derived for the G₁-G_{3′} map because this Zernike term most closely maps to the gravitational force. The Zernike factor z5(G₁-G_{3′}) corresponds to the orientation factor because, for purposes disclosed herein, it describes the magnitude of the z5 astigmatism term associated with the gravitational error and is derived from two different orientated maps. It is noted that in calculation (8) above, the W terms do not actually cancel out, but the difference in W when calculating F₁-F_{3′} is very small. Therefore, for purposes disclosed herein, the W terms are considered to cancel out in the calculation of (8) above.

Various steps of process 300 (such as steps 345 and 350) use orthogonal polynomials to characterize and describe the measurements calculated herein. In embodiments, the orthogonal polynomials utilized may include, for example, Zernike polynomials, Legendre polynomials, and X-Y polynomials. For purposes of the steps of process 300, as shown in FIG. 3, Zernike polynomials are shown and described. However, the steps of process 300 should not limited to such Zernike polynomials and may use other orthogonal polynomials.

At step 345, the first difference measurement produced in calculation (4) above (G₁-G₂) is fit to a Zernike polynomial to derive the z5 astigmatism Zernike factor, which is referred to herein as: z5(G₁-G₂). The z5 astigmatism factor is associated with a fifth Zernike polynomial (20). The z5 astigmatism Zernike factor is derived for the first difference measurement because this Zernike term most closely describes the magnitude of the first difference measurement which describes the shape of the gravitational error. The Zernike factor z5(G₁-G₂) corresponds to a tilt factor because, for purposes disclosed herein, it describes the magnitude of the difference measurement derived from two different tilted maps.

At step 355, a first scale factor R₁ is calculated as follows by dividing the above calculated orientation factor by the above calculated tilt factor:

$$R 1 = \frac{z 5 ( G 1 - G {3}^{′} )}{z 5 ( G 1 - G 2 )} \qquad ( 9 )$$

The R₁ term calculated above corresponds to a scale factor because, for purposes disclosed herein, it provides scaling information of the different maps generated from the first and second flatness measurements.

At step 365, the first difference measurement produced in calculation (4) above (G₁-G₂) is multiplied by the first scale factor R₁ to generate the deviation in flatness caused from the gravitational force. This calculation is shown as:

$${R}_{1} \times ( {G}_{1} - {G}_{2} ) == {G}_{1} \qquad ( 10 )$$

wherein G₁ is the deviation in flatness caused from the gravitational force, as discussed above.

At step 375, the deviation in flatness caused from the gravitational force (G₁), as calculated using calculation (10) above, is subtracted from the first flatness measurement F₁ (wherein F₁ is shown in equation (2) above), as shown in calculation (11):

$${F}_{1} - {G}_{1} = {M}_{0} \qquad ( 11 )$$

wherein M₀ is the true flatness of the substrate 130 without the influence of the gravitational force, as discussed above.

The true flatness M₀ calculated using calculation (11) can be further revised by combining this calculation with the measurements from the third and fourth flatness measurements. Moving back to step 350 of process 300, the second difference measurement produced in calculation (7) above (G₃-G₄) is fit to a Zernike polynomial to derive the z5 astigmatism Zernike factor, which is referred to herein as: z5(G₃-G₄). The z5 astigmatism factor is associated with a fifth order Zernike polynomial (20). The z5 astigmatism Zernike factor is derived for the second difference measurement because this Zernike term most closely describes the magnitude of the second difference measurement. The Zernike factor z5(G₃-G₄) corresponds to a tilt factor because, for purposes disclosed herein, it describes the magnitude of the difference measurement derived from two different tilted maps.

At step 360, a second scale factor R₂ is calculated as follows by dividing the above calculated orientation factor by the above calculated tilt factor:

$$R 2 = \frac{z 5 ( G 1 - G {3}^{′} )}{z 5 ( G 3 - G 4 )} \qquad ( 12 )$$

The R₂ term calculated above corresponds to a scale factor because, for purposes disclosed herein, it provides scaling information of the different maps generated from the third and fourth flatness measurements.

In some embodiments, the second scale factor R₂ is calculated by first determining a second orientation factor (rather than using the orientation factor calculated above, which uses the first flatness measurement and the modified third flatness measurement with calculation (8)). The second orientation, in embodiments, is calculated by subtracting the modified fourth flatness measurement F₄, from the second flatness measurement F₂, which provides a G₂-G_{4′} map. This map is then fit to a Zernike polynomial to derive the z5 astigmatism Zernike factor, which is referred to herein as: z5(G₂-G₄°). The z5 astigmatism factor is associated with a fifth order Zernike polynomial (2θ). The Zernike factor z5(G₂-G₄°) corresponds to the second orientation factor because, for purposes disclosed herein, it describes the magnitude of the z5 astigmatism term associated with the gravitational error and is derived from two different orientated maps.

At step 370, the second difference measurement produced in calculation (7) above (G₃-G₄) is multiplied by the second scale factor R₂ to generate the deviation in flatness caused from the gravitational force. This calculation is shown as:

$${R}_{2} \times ( {G}_{3} - {G}_{4} ) = {G}_{3} \qquad ( 13 )$$

wherein G₃ is the deviation in flatness caused from the gravitational force, as discussed above.

At step 380, the deviation in flatness caused from the gravitational force (G₃), as calculated using calculation (13) above, is subtracted from the third flatness measurement F₃ (wherein F₃ is shown in equation (5) above), as shown in calculation (14):

$${F}_{3} - {G}_{3} = {M}_{90} \qquad ( 14 )$$

wherein M₉₀ is the true flatness of the substrate 130 without the influence of the gravitational force, as also discussed above.

At step 385, the true flatness measurements M₀ and M₉₀ may then be averaged together to provide a more precise true flatness measurement. In embodiments, the data set of the flatness measurement M₉₀ is rotated 90 degrees in order to average it with the data set of the flatness measurement M₀.

As noted above, the order of the steps of process 300 may be arranged and changed. For example, the flatness measurements in steps 305, 310, 315, and/or 320 may each be fit to a Zernike polynomial before the difference measurements are calculated in steps 325 and 330. Furthermore, the true flatness of the substrate 130 may be calculated without using steps 320, 330, 350, 360, 370, 380, and 385.

After identifying deviations in the flatness of the substrate 130, the deviations may be accounted for during patterning the semiconductor material. In some examples, accounting for the deviations may include modifying a pattern (e.g., pattern data) that is printed in the substrate 130 to compensate for printing errors that could result from the deviations. In some examples, accounting for the deviations may include modifying a placement of patterned data on the substrate 130 to reduce an impact of deviations of the flatness when patterning the semiconductor material. After accounting for the deviations, the semiconductor material may be patterned using the modified substrate 130. Similarly, the deviations of the flatness can also be transmitted to one or more processors for use in the manufacturing process of photomasks, such that the deviations may be reduced during manufacturing. For example, the surface of the substrate 130 may be deterministically polished to remove the deviation of the flatness.

In accordance with performing the techniques described herein, these techniques may separate deviations in the flatness of the substrate 130 induced by gravitational force from a true flatness of the substrate 130. Therefore, performing the techniques described herein may provide a more accurate measurement of the flatness of the substrate 130. Further, using two orientations to generate the respective flatness measurements may decrease latency for determining the true flatness of the substrate 130 and increase a throughput for measuring flatnesses of additional photomasks at the system 100. Additionally, performing the techniques described herein may enable using Zernike polynomials to scale deformation induced by gravitational force for generating the estimations of the error, which may be more accurate than using force measurements to scale the deformation. And the methods described herein may be configured to account for rotationally symmetric errors which may have been otherwise unaccounted for in previous implementations.

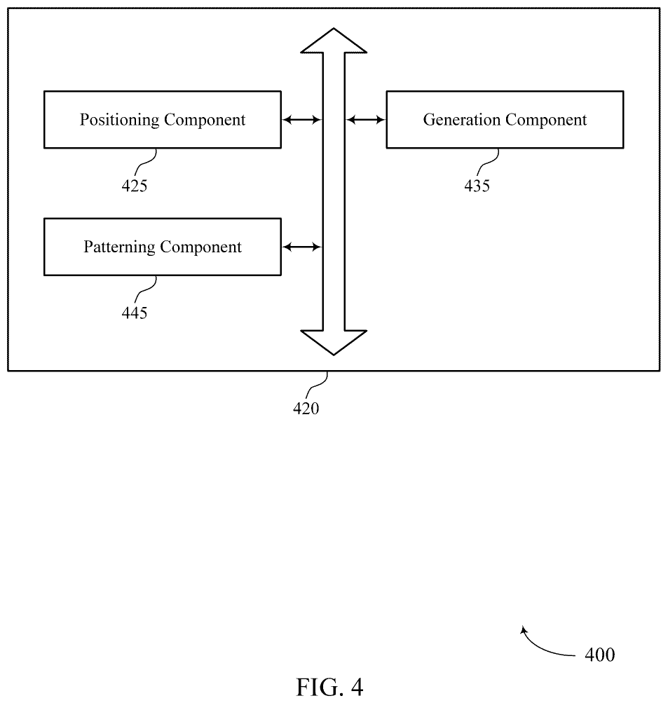

FIG. 4 shows a block diagram 400 of a substrate measurement system 420 that supports error resistant substrate measurement techniques for different support positions in accordance with aspects of the present disclosure. The substrate measurement system 420 may be an example of aspects of a substrate measurement system as described with reference to FIGS. 1 through 3. The substrate measurement system 420, or various components thereof, may be an example of means for performing various aspects of error resistant substrate measurement techniques for different support positions as described herein. For example, the substrate measurement system 420 may include a positioning component 425, a generation component 435, and a patterning component 445, or any combination thereof. Each of these components may communicate, directly or indirectly, with one another (e.g., via one or more buses).

The positioning component 425 may be configured as or otherwise support a means for positioning a substrate to be in contact with one or more support points. The generation component 435 may be configured as or otherwise support a means for measuring, via one or more interferometers, the first, second, third, and fourth flatness measurements. The generation component 435 may also be configured as or otherwise support a means for generating a difference measurement between the first flatness measurement and the second flatness measurement and/or for generating a difference measurement between the third flatness measurement and the fourth flatness measurement. The mapping component 440 may be configured as or otherwise support a means for fitting each difference measurement to a respective Zernike polynomial. In some examples, the generation component 435 may be configured as or otherwise support a means for generating an estimation of an error based at least in part on using a scale factor and the difference measurements, the scale factor based on extracting Zernike factors associated with the Zernike polynomial.

In some examples, the patterning component 445 may be configured as or otherwise support a means for patterning a semiconductor material based at least in part on modifying a positioning of patterned data on the substrate based at least in part on using the flatness measurements generated herein.

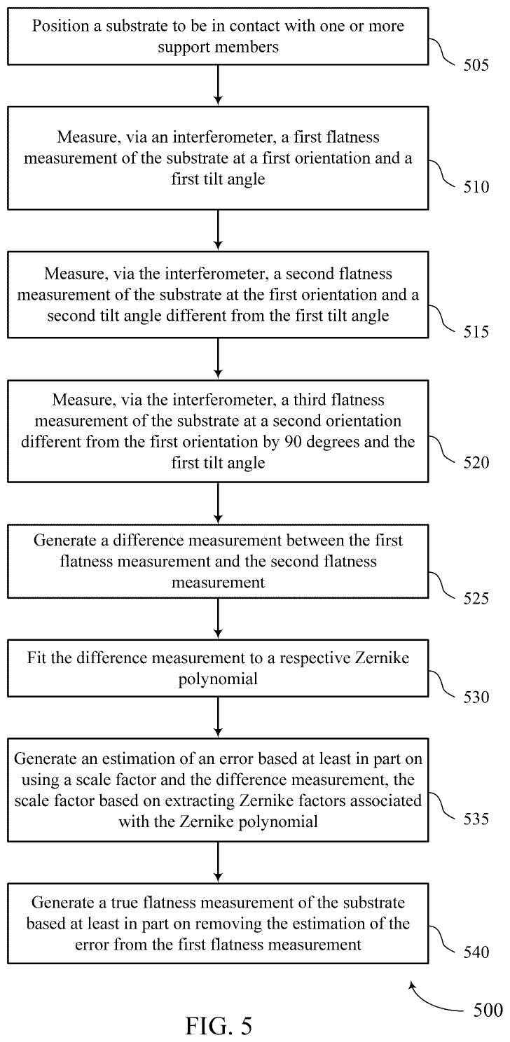

FIG. 5 shows a flowchart illustrating a method 500 that supports error resistant substrate measurement techniques for different support positions in accordance with aspects of the present disclosure. The operations of the method 500 may be implemented by a substrate measurement system or its components as described herein. For example, the operations of the method 500 may be performed by a substrate measurement system as described with reference to FIGS. 1 through 4. In some examples, a substrate measurement system may execute a set of instructions to control the functional elements of the wireless substrate measurement system to perform the described functions. Additionally, or alternatively, the wireless substrate measurement system may perform aspects of the described functions using special-purpose hardware.

At 505, the method may include positioning a substrate to be in contact with one or more support members. The operations of 505 may be performed in accordance with examples as disclosed herein. In some examples, aspects of the operations of 505 may be performed by a positioning component 425 as described with reference to FIG. 4.

At 510, the method may include measuring, via the interferometer, a first flatness measurement of the substrate at a first orientation and a first tilt angle. The operations of 510 may be performed in accordance with examples as disclosed herein. In some examples, aspects of the operations of 510 may be performed by a generation component 435 as described with reference to FIG. 4.

At 515, the method may include measuring, via the interferometer, a second flatness measurement of the substrate at the first orientation and a second tilt angle different from the first tilt angle. The operations of 515 may be performed in accordance with examples as disclosed herein. In some examples, aspects of the operations of 515 may be performed by a generation component 435 as described with reference to FIG. 4.

At 520, the method may include measuring, via the interferometer, a third flatness measurement of the substrate at a second orientation different from the first orientation by 90 degrees and the first tilt angle. The operations of 420 may be performed in accordance with examples as disclosed herein. In some examples, aspects of the operations of 520 may be performed by a generation component 435 as described with reference to FIG. 4.

At 525, the method may include generating a difference measurement between the first flatness measurement and the second flatness measurement. The operations of 525 may be performed in accordance with examples as disclosed herein. In some examples, aspects of the operations of 525 may be performed by a generation component 435 as described with reference to FIG. 4.

At 530, the method may include fitting the difference measurement to a respective Zernike polynomial. The operations of 530 may be performed in accordance with examples as disclosed herein. In some examples, aspects of the operations of 530 may be performed by a generation component 435 as described with reference to FIG. 4.

At 535, the method may include generating an estimation of an error based at least in part on using a scale factor and the difference measurement, the scale factor based on extracting Zernike factors associated with the Zernike polynomial. The operations of 535 may be performed in accordance with examples as disclosed herein. In some examples, aspects of the operations of 535 may be performed by a generation component 435 as described with reference to FIG. 4.

At 540, the method may include generating a true flatness measurement of the substrate based at least in part on removing the estimation of the error from the first flatness measurement. The operations of 540 may be performed in accordance with examples as disclosed herein. In some examples, aspects of the operations of 540 may be performed by a generation component 435 as described with reference to FIG. 4.

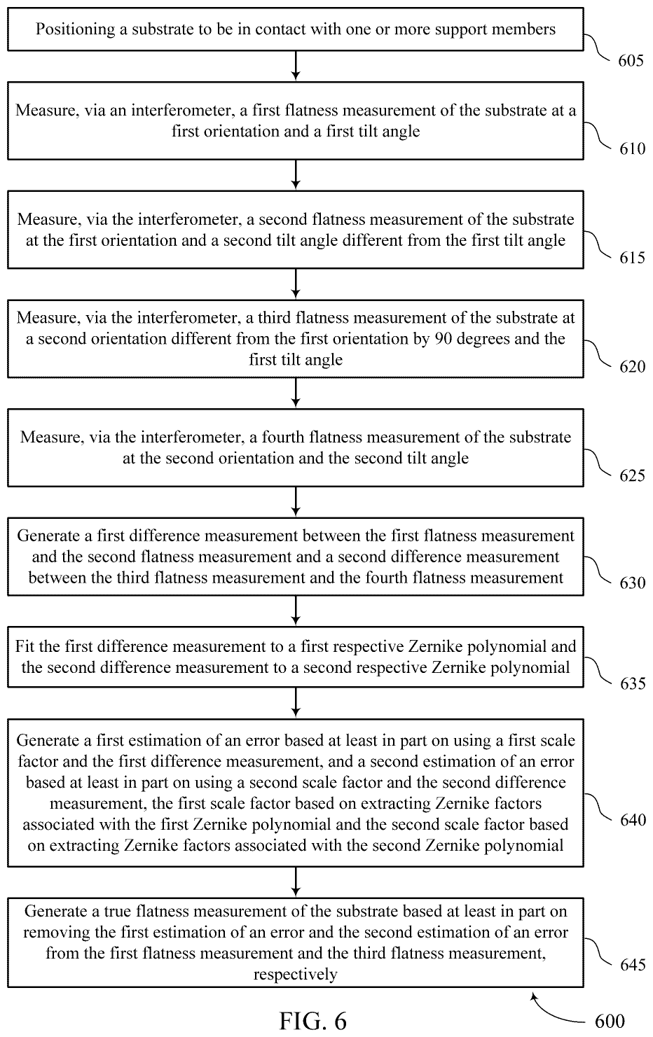

FIG. 6 shows a flowchart illustrating a method 600 that supports error resistant substrate measurement techniques for different support positions in accordance with aspects of the present disclosure. The operations of the method 600 may be implemented by a substrate measurement system or its components as described herein. For example, the operations of the method 600 may be performed by a substrate measurement system as described with reference to FIGS. 1 through 4. In some examples, a substrate measurement system may execute a set of instructions to control the functional elements of the substrate measurement system to perform the described functions. Additionally, or alternatively, the substrate measurement system may perform aspects of the described functions using special-purpose hardware.

At 605, the method may include positioning a substrate to be in contact with one or more support members. The operations of 605 may be performed in accordance with examples as disclosed herein. In some examples, aspects of the operations of 605 may be performed by a positioning component 425 as described with reference to FIG. 4.

At 610, the method may include measuring, via the interferometer, a first flatness measurement of the substrate at a first orientation and a first tilt angle. The operations of 610 may be performed in accordance with examples as disclosed herein. In some examples, aspects of the operations of 610 may be performed by a generation component 435 as described with reference to FIG. 4.

At 615, the method may include measuring, via the interferometer, a second flatness measurement of the substrate at the first orientation and a second tilt angle different from the first tilt angle. The operations of 615 may be performed in accordance with examples as disclosed herein. In some examples, aspects of the operations of 615 may be performed by a generation component 435 as described with reference to FIG. 4.

At 620, the method may include measuring, via the interferometer, a third flatness measurement of the substrate at a second orientation different from the first orientation by 90 degrees and the first tilt angle. The operations of 620 may be performed in accordance with examples as disclosed herein. In some examples, aspects of the operations of 620 may be performed by a generation component 435 as described with reference to FIG. 4.

At 625, the method may include measuring, via the one or more interferometers, a fourth flatness measurement of the substrate at the second orientation and the second tilt angle. The operations of 625 may be performed in accordance with examples as disclosed herein. In some examples, aspects of the operations of 625 may be performed by a generation component 435 as described with reference to FIG. 4.

At 630, the method may include generating a first difference measurement between the first flatness measurement and the second flatness measurement and a second difference measurement between the third flatness measurement and the fourth flatness measurement. The operations of 630 may be performed in accordance with examples as disclosed herein. In some examples, aspects of the operations of 630 may be performed by a generation component 435 as described with reference to FIG. 4.

At 635, the method may include fitting the first difference measurement to a first respective Zernike polynomial and the second difference measurement to a second respective Zernike polynomial. The operations of 635 may be performed in accordance with examples as disclosed herein. In some examples, aspects of the operations of 635 may be performed by a generation component 435 as described with reference to FIG. 4.

At 640, the method may include generating a first estimation of an error based at least in part on using a first scale factor and the first difference measurement, and a second estimation of an error based at least in part on using a second scale factor and the second difference measurement, the first scale factor based on extracting Zernike factors associated with the first Zernike polynomial and the second scale factor based on extracting Zernike factors associated with the second Zernike polynomial. The operations of 640 may be performed in accordance with examples as disclosed herein. In some examples, aspects of the operations of 640 may be performed by a generation component 435 as described with reference to FIG. 4.

At 645, the method may include generating a true flatness measurement of the substrate based at least in part on removing the first estimation of an error and the second estimation of an error from the first flatness measurement and the third flatness measurement, respectively. The operations of 645 may be performed in accordance with examples as disclosed herein. In some examples, aspects of the operations of 645 may be performed by a generation component 435 as described with reference to FIG. 4.

It should be noted that these methods describe examples of implementations, and that the operations and the steps may be rearranged or otherwise modified such that other implementations are possible. In some examples, aspects from two or more of the methods may be combined. For example, aspects of each of the methods may include steps or aspects of the other methods, or other steps or techniques described herein. Thus, aspects of the disclosure may provide for consumer preference and maintenance interface.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and devices are shown in block diagram form in order to avoid obscuring the concepts of the described examples.

Information and signals described herein may be represented using any of a variety of different technologies and techniques. For example, data, instructions, commands, information, signals, bits, and symbols that may be referenced throughout the above description may be represented by voltages, currents, electromagnetic waves, magnetic fields or particles, optical fields or particles, or any combination thereof.

The various illustrative blocks and modules described in connection with the disclosure herein may be implemented or performed with a general-purpose processor, a digital signal processor (DSP), an application-specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration). The functions of each unit may also be implemented, in whole or in part, with instructions embodied in a memory, formatted to be executed by one or more general or application-specific processors.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

The description herein is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method of determining a flatness of a substrate, the method comprising:
measuring a first flatness measurement of the substrate at a first orientation and a first tilt angle;
measuring a second flatness measurement of the substrate at the first orientation and a second tilt angle different from the first tilt angle;
generating a difference measurement between the first flatness measurement and the second flatness measurement;
fitting the difference measurement to an orthogonal polynomial;
generating an estimation of error based at least in part on using a scale factor and the difference measurement, the scale factor based on extracting orthogonal factors associated with the orthogonal polynomial; and
generating a true flatness of the substrate by removing the estimation of error from the first flatness measurement.

2. The method of claim 1, wherein the orthogonal polynomial is a Zernike polynomial.

3. The method of claim 1, wherein the second orientation is rotated 90 degrees from the first orientation.

4. The method of claim 1, wherein the substrate is a photomask.

5. The method of claim 1, further comprising:
measuring a third flatness measurement of the substrate at a second orientation different from the first orientation and the first tilt angle;
rotating the third flatness measurement to match an orientation of the first flatness measurement to generate a modified third flatness measurement; and
subtracting the modified third flatness measurement from the first flatness measurement to generate an orientation factor.

6. The method of claim 1, further comprising dividing an orientation factor by a tilt factor to provide a scale factor and multiplying the first difference measurement by the scale factor to provide the estimation of error.

7. The method of claim 6, further comprising subtracting the estimation of error from the first flatness measurement to provide the true flatness of the substrate.

8. The method of claim 6, wherein the estimation of error is a deviation in flatness of the substrate caused from a gravitational force.

9. The method of claim 6, further comprising:
measuring a third flatness measurement of the substrate at a second orientation different from the first orientation and the first tilt angle;
rotating the third flatness measurement to match an orientation of the first flatness measurement to generate a modified third flatness measurement;
subtracting the modified third flatness measurement from the first flatness measurement to generate the orientation factor; and
fitting the difference measurement to an orthogonal polynomial to generate the tilt factor.

10. The method of claim 9, wherein the orthogonal polynomial is a Zernike polynomial.

11. The method of claim 1, further comprising:
patterning a semiconductor material based at least in part on modifying a positioning of patterned data on the substrate based at least in part on the true flatness of the substrate.

12. The method of claim 1, further comprising:
measuring a third flatness measurement of the substrate at a second orientation different from the first orientation and the first tilt angle;
measuring a fourth flatness measurement of the substrate at the second orientation and the second tilt angle;
generating a second difference measurement between the third flatness measurement and the fourth flatness measurement; and
fitting the second difference measurement to an orthogonal polynomial.

13. The method of claim 12, wherein the orthogonal polynomial is a Zernike polynomial.

14. The method of claim 12, further comprising:
generating a second estimation of error based at least in part on using a scale factor and the second difference measurement, the scale factor based on extracting orthogonal factors associated with the orthogonal polynomial; and
generating the true flatness of the substrate by removing the second estimation of error from the third flatness measurement.

15. The method of claim 14, further comprising averaging the difference from removing the estimation of error from the first flatness measurement with the difference from removing the second estimation of error from the third flatness measurement to generate the true flatness of the substrate.

16. The method of claim 1, wherein the first flatness measurement and the second flatness measurement are each measured by directing light at the substrate and comparing the light with light directed at a reference surface.

17. The method of claim 1, wherein the first tilt angle and the second tilt angle are each less than about 5 degrees.

18. The method of claim 1, wherein the first tilt angle is from about 1 degree to about 2 degrees and the second tilt angle is from about 3 degrees to about 4 degrees.

19. The method of claim 1, further comprising positioning the substrate in contact with one or more support members of an interferometer.

20. A method of determining a flatness of a substrate, the method comprising:
measuring a first flatness measurement of the substrate at a first orientation and a first tilt angle;
measuring a second flatness measurement of the substrate at the first orientation and a second tilt angle different from the first tilt angle;
fitting the first flatness measurement to a first orthogonal polynomial and the second flatness measurement to a second orthogonal polynomial;
generating a difference measurement between the first orthogonal polynomial and the second orthogonal polynomial;
generating an estimation of error based at least in part on using a scale factor and the difference measurement; and
generating a true flatness of the substrate by removing the estimation of error from the first flatness measurement.
